(19) United States
(12) Patent Application Publication
(10) Pub. No.: US 2014/0367763 A1
(43) Pub. Date: Dec. 18, 2014

(54) SEMICONDUCTOR MEMORY DEVICE

(71) Applicant: KABUSHIKI KAISHA TOSHIBA, Minato-ku (JP)

(72) Inventor: Naoki YASUDA, Mie-ken (JP)

(73) Assignee: KABUSHIKI KAISHA TOSHIBA, Minato-ku (JP)

(21) Appl. No.: 14/162,235

(22) Filed: Jan. 23, 2014

(30) Foreign Application Priority Data
Jun. 13, 2013 (JP) 2013-124635

(51) Int. Cl. H01L 29/792; H01L 27/115; H01L 29/51

(52) U.S. Cl. CPC H01L 29/792; H01L 29/513; H01L 27/11578
USPC 257/324

(57) ABSTRACT

According to one embodiment, the tunnel insulating film contains silicon, oxygen, and nitrogen, and including at least a first tunnel insulating film provided on the semiconductor channel side and a second tunnel insulating film provided on the charge storage film side. The first insulating film is provided on a surface of the first tunnel insulating film on opposite side from a surface on the semiconductor channel side. The first insulating film has a lower surface density of oxygen atoms than the first tunnel insulating film, and has a higher permittivity than silicon nitride.

### CROSS-REFERENCE TO RELATED APPLICATION

This application is based upon and claims the benefit of priority from Japanese Patent Application No. 2013-124635, filed on Jun. 13, 2013; the entire contents of which are incorporated herein by reference.

### FIELD

Embodiments described herein relate generally to a semiconductor memory device.

### BACKGROUND

With regard to nonvolatile semiconductor memory devices, there is a proposal for improving memory cell characteristics by providing a high-k insulating film between the tunnel insulating film and the semiconductor region or between the tunnel insulating film and the charge storage film.

### BRIEF DESCRIPTION OF THE DRAWINGS

FIG. 1 is a schematic perspective view of a memory cell array of a semiconductor memory device of an embodiment;

FIG. 2A is a schematic sectional view of a memory cell of a semiconductor memory device of a first embodiment;

FIG. 2B is a band diagram under application of electric field to a tunnel insulating film of the memory cell of the semiconductor memory device of the first embodiment;

FIG. 3 is a current-electric field characteristic diagram of the tunnel insulating film of the memory cell of the semiconductor memory device of the first embodiment;

FIG. 4A is a schematic sectional view of a memory cell of a semiconductor memory device of a second embodiment;

FIG. 4B is a band diagram under application of electric field to a tunnel insulating film of the memory cell of the semiconductor memory device of the second embodiment;

FIG. 5 is a current-electric field characteristic diagram of the tunnel insulating film of the memory cell of the semiconductor memory device of the second embodiment;

FIG. 6A is a schematic sectional view of a memory cell of a semiconductor memory device of a third embodiment;

FIG. 6B is a band diagram under application of electric field to a tunnel insulating film of the memory cell of the semiconductor memory device of the third embodiment;

FIG. 7 is a current-electric field characteristic diagram of the tunnel insulating film of the memory cell of the semiconductor memory device of the third embodiment;

FIG. 8A is a schematic sectional view of a memory cell of a semiconductor memory device of a fourth embodiment;

FIG. 8B is a band diagram under application of electric field to a tunnel insulating film of the memory cell of the semiconductor memory device of the fourth embodiment;

FIG. 9 is a current-electric field characteristic diagram of the tunnel insulating film of the memory cell of the semiconductor memory device of the fourth embodiment;

FIG. 10 is schematic sectional view of a memory cell of a semiconductor memory device of a fifth embodiment; and

FIGS. 11A and 11B are schematic sectional views of the memory cell of the semiconductor memory device of the fifth embodiment.

### DETAILED DESCRIPTION

According to one embodiment, a semiconductor memory device includes a semiconductor channel; an electrode layer; a charge storage film provided between the semiconductor channel and the electrode layer; a tunnel insulating film; and a first insulating film. The tunnel insulating film is provided between the semiconductor channel and the charge storage film. The tunnel insulating film contains silicon, oxygen, and nitrogen, and including at least a first tunnel insulating film provided on the semiconductor channel side and a second tunnel insulating film provided on the charge storage film side. The first insulating film is provided on a surface of the first tunnel insulating film on opposite side from a surface on the semiconductor channel side. The first insulating film has a lower surface density of oxygen atoms than the first tunnel insulating film, and has a higher permittivity than silicon nitride.

Embodiments will now be described with reference to the drawings. In the drawings, like elements are labeled with like reference numerals.

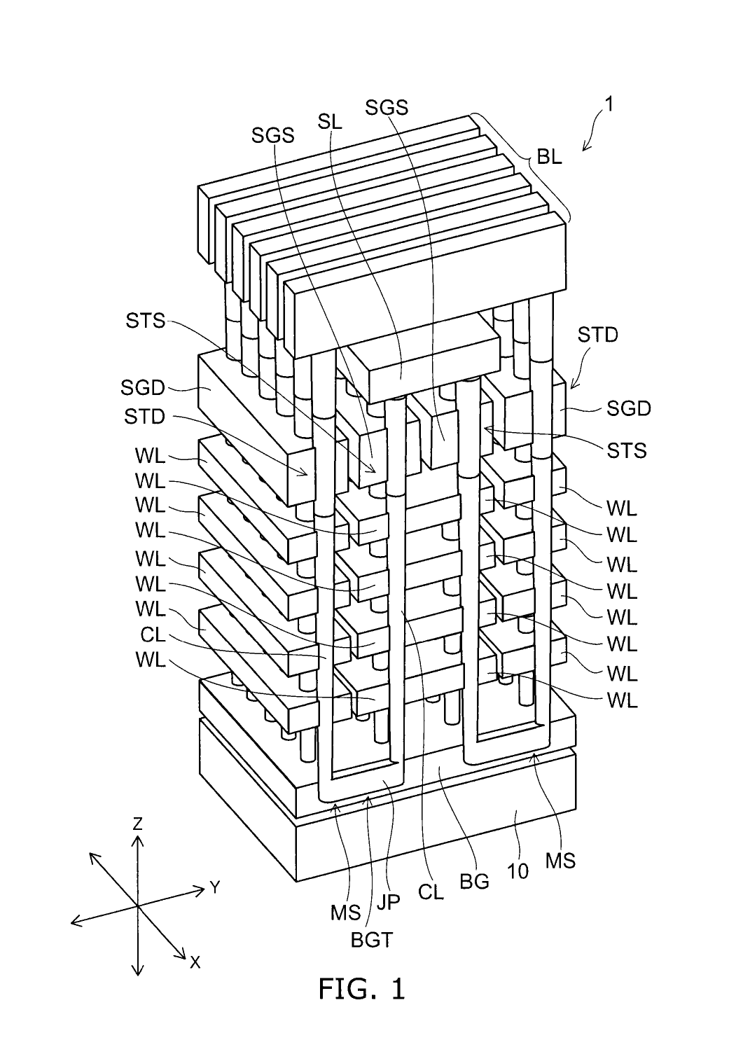

FIG. 1 is a schematic perspective view of a memory cell array 1 of a semiconductor memory device of the embodiments. In FIG. 1, for clarity of illustration, the insulating layer between the electrode layers WL, and the insulating separation film for separating the stacked body into a plurality of blocks, for instance, are not shown.

In FIG. 1, two directions parallel to the major surface of the substrate 10 and orthogonal to each other are referred to as Y-direction (first direction) and X-direction (second direction). The direction orthogonal to both the Y-direction and the X-direction is referred to as Z-direction (third direction or stacking direction).

The memory cell array 1 of the embodiments includes a stacked body in which a plurality of electrode layers WL and insulating layers are stacked alternately one by one. This stacked body is provided on a back gate BG serving as a lower gate layer. Here, the number of electrode layers WL shown in the figure is illustrative only. The number of electrode layers WL is arbitrary.

The back gate BG is provided via an insulating layer on the substrate 10. The back gate BG and the electrode layer WL are conductive layers, such as silicon layers doped with impurity.

The memory cell array 1 includes a plurality of memory strings MS. One memory string MS is formed in a U-shape including a pair of columnar parts CL extending in the Z-direction, and a joining part JP joining the respective lower ends of the pair of columnar parts CL. The columnar part CL is formed in e.g. a cylindrical shape, and penetrates through the stacked body.

In one upper end part of the pair of columnar parts CL in the U-shaped memory string MS, a drain side select gate SGD is provided. In the other upper end part, a source side select gate SGS is provided. The drain side select gate SGD and the source side select gate SGS as upper select gates are provided via an insulating layer on the uppermost electrode layer WL.

The drain side select gate SGD and the source side select gate SGS are e.g. silicon layers doped with impurity.

The drain side select gate SGD and the source side select gate SGS are separated in the Y-direction by an insulating separation film. The stacked body below the drain side select gate SGD and the stacked body below the source side select gate SGS are also separated in the Y-direction by an insulating separation film. That is, the stacked body between the pair of columnar parts CL of the memory string MS is separated in the Y-direction by an insulating separation film.

On the source side select gate SGS, a source line (e.g., metal film) SL is provided via an insulating layer. On the drain side select gate SGD and the source line SL, a plurality of bit lines (e.g., metal films) BL are provided via an insulating layer. Each bit line BL extends in the Y-direction.

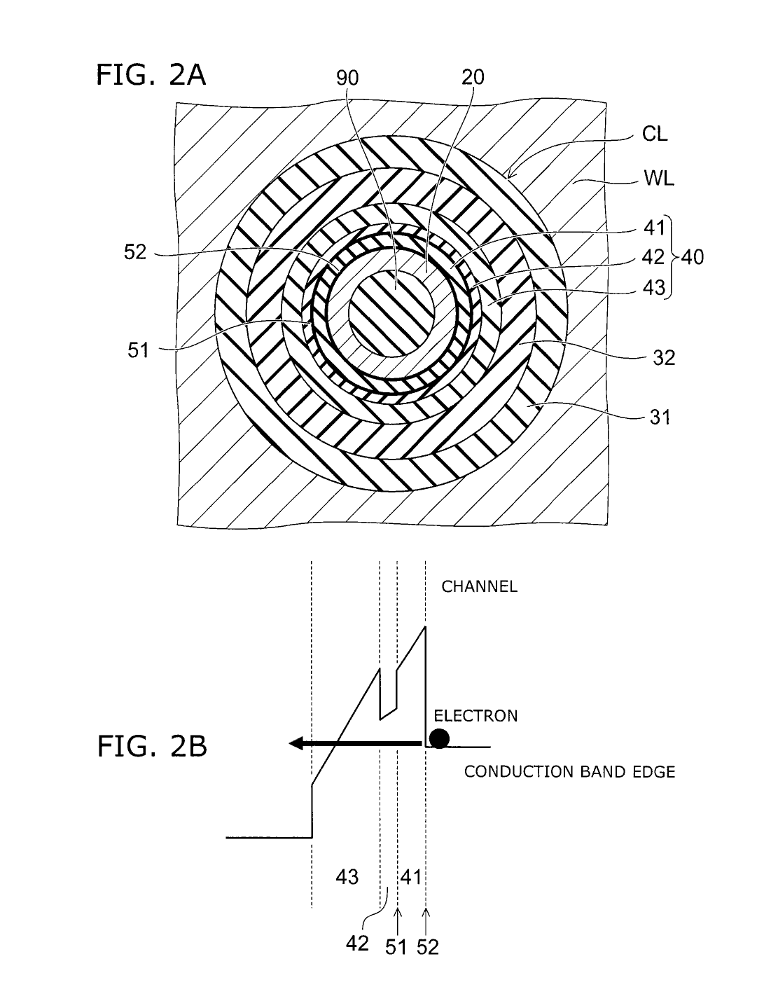

FIG. 2A is a schematic sectional view of a memory cell in the semiconductor memory device of a first embodiment. FIG. 2A shows a cross section along the diameter direction of the columnar part CL of the memory string MS.

The columnar part CL is provided in a U-shaped memory hole formed in the stacked body including the back gate BG, the plurality of electrode layers WL, and interelectrode insulating layers.

In the U-shaped memory hole, a channel body 20 as a semiconductor channel is provided. The channel body 20 is e.g. a silicon film. The impurity concentration of the channel body 20 is lower than the impurity concentration of the electrode layer WL.

A memory film is provided between the inner wall of the memory hole and the channel body 20. The memory film includes a block film 31, a charge storage film 32, and a tunnel insulating film 40. Between the electrode layer WL and the channel body 20, sequentially from the electrode layer WL side, the block film 31, the charge storage film 32, and the tunnel insulating film 40 are provided.

The channel body 20 is provided in a tubular shape. The memory film in a tubular shape is provided so as to surround the outer peripheral surface of the channel body 20. The electrode layer WL surrounds the periphery of the channel body 20 via the memory film. Inside the channel body 20, a core insulating film 90 is provided. The core insulating film 90 is e.g. a silicon oxide film.

The block film 31 is in contact with the electrode layer WL. The tunnel insulating film 40 is in contact with the channel body 20. The charge storage film 32 is provided between the block film 31 and the tunnel insulating film 40.

The channel body 20 functions as a channel in a memory cell. The electrode layer WL functions as a control gate of the memory cell. The charge storage film 32 functions as a data memory layer for accumulating charge injected from the channel body 20. That is, at the intersection of the channel body 20 and each electrode layer WL, a memory cell having a structure with the channel surrounded with the control gate is formed.

The semiconductor memory device of the embodiments is a nonvolatile semiconductor memory device capable of electrically and freely erasing/writing data and retaining its memory content even when powered off.

The memory cell is e.g. a charge trap type memory cell. The charge storage film 32 includes a large number of trap sites for trapping charge, and is e.g. a silicon nitride film.

The block film 31 is e.g. a silicon oxide film, a silicon nitride film, or a multilayer film thereof, and prevents the charge accumulated in the charge storage film 32 from diffusing into the electrode layer WL.

The tunnel insulating film 40 serves as a potential barrier when a charge is injected from the channel body 20 into the charge storage film 32, or when the charge accumulated in the charge storage film 32 is diffused into the channel body 20. As described later, the tunnel insulating film 40 is a multilayer film of a plurality of films.

As shown in FIG. 1, in one upper end part of the pair of columnar parts CL in the U-shaped memory string MS, a drain side select transistor STD is provided. In the other upper end part, a source side select transistor STS is provided.

The memory cell, the drain side select transistor STD, and the source side select transistor STS are vertical transistors in which the current flows in the Z-direction.

The drain side select gate SGD functions as a gate electrode (control gate) of the drain side select transistor STD. Between the drain side select gate SGD and the channel body 20, an insulating film (not shown) functioning as a gate insulating film of the drain side select transistor STD is provided. The channel body of the drain side select transistor STD is connected to the bit line BL above the drain side select gate SGD.

The source side select gate SGS functions as a gate electrode (control gate) of the source side select transistor STS. Between the source side select gate SGS and the channel body 20, an insulating film (not shown) functioning as a gate insulating film of the source side select transistor STS is provided. The channel body of the source side select transistor STS is connected to the source line SL above the source side select gate SGS.

In the joining part JP of the memory string MS, a back gate transistor BGT is provided. The back gate BG functions as a gate electrode (control gate) of the back gate transistor BGT. The memory film provided in the back gate BG functions as a gate insulating film of the back gate transistor BGT.

Between the drain side select transistor STD and the back gate transistor BGT, a plurality of memory cells with the respective electrode layers WL serving as control gates are provided. Likewise, also between the back gate transistor BGT and the source side select transistor STS, a plurality of memory cells with the respective electrode layers WL serving as control gates are provided.

The plurality of memory cells, the drain side select transistor STD, the back gate transistor BGT, and the source side select transistor STS are series connected through the channel body 20 to constitute one U-shaped memory string MS. This memory string MS is arranged in a plurality in the X-direction and the Y-direction. Thus, a plurality of memory cells are provided three-dimensionally in the X-direction, the Y-direction, and the Z-direction.

The tunnel insulating film 40 is provided between the channel body 20 and the charge storage film 32, and contains silicon, oxygen, and nitrogen.

The tunnel insulating film 40 includes a first tunnel insulating film 41, a second tunnel insulating film 43, and a third tunnel insulating film 42. Such a tunnel insulating film 40 made of a multilayer film of a plurality of films is superior in e.g. erasure characteristics.

The first tunnel insulating film 41 is provided in a tubular shape around the channel body 20. The first tunnel insulating film 41 is e.g. a silicon oxide film.

The second tunnel insulating film 43 is provided in a tubular shape on the inner peripheral surface of the charge storage film 32. The second tunnel insulating film 43 is e.g. a silicon oxide film.

The third tunnel insulating film 42 is provided in a tubular shape between the first tunnel insulating film 41 and the second tunnel insulating film 43. The third tunnel insulating film 42 has a higher nitrogen concentration than the first tunnel insulating film 41 and the second tunnel insulating film 43. The third tunnel insulating film 42 is e.g. a silicon nitride film or silicon oxynitride film. The term “nitrogen concentration” used herein refers to the volume density of nitrogen (the number of nitrogen atoms per unit volume).

Here, the multilayer film of a high-k insulating film and a silicon oxide film (SiO₂ film) is considered. In the case where the high-k insulating film has a lower surface density of oxygen atoms than the SiO₂ film, the number of oxygen atoms is not matched at the interface between the SiO₂ film and the high-k insulating film. The interface is stabilized by transport of oxygen in the direction of matching the number of oxygen atoms, i.e., from the SiO₂ film side to the high-k insulating film side. Thus, a dipole is formed at the interface. More specifically, an oxygen atom having a negative charge is generated in the high-k insulating film, and an oxygen vacancy having a positive charge is generated in the SiO₂ film. Thus, an interface dipole is generated with the high-k insulating film side charged negative.

On the other hand, in the case where the high-k insulating film has a higher surface density of oxygen atoms than the SiO₂ film, oxygen is transported in the direction of matching the number of oxygen atoms, i.e., from the high-k insulating film side to the SiO₂ film. More specifically, an oxygen vacancy having a positive charge is generated in the high-k insulating film, and an oxygen atom having a negative charge is generated in the SiO₂ film. Thus, an interface dipole is generated with the high-k insulating film side charged positive.

The generation of such a dipole at the interface between the high-k insulating film and the SiO₂ film causes a threshold voltage shift of the transistor including the multilayer film as a gate insulating film (tunnel insulating film). Furthermore, it also affects the writing/erasure characteristics of the transistor by the modulation of the band profile of the insulating film.

Compared with a monolayer tunnel insulating film, the tunnel insulating film made of a multilayer film of a plurality of films has a higher degree of freedom capable of modulating the barrier height by placing the high-k insulating film at the interface of the respective layers. Thus, the inventor diligently studied to determine what kind of high-k insulating film placed at the interface of the respective layers of the tunnel insulating film made of a multilayer film of a plurality of films leads to a steep current-electric field characteristic. Accordingly, the result described below was obtained.

In this specification, the high-k insulating film refers to an insulating film having a higher permittivity than the silicon nitride film, and made of e.g. metal oxide, nitride, oxynitride, silicate, aluminate, nitride silicate, or nitride aluminate.

In this specification, the barrier height or conduction band barrier height of the insulating film refers to the value with reference to the energy of the conduction band edge of silicon.

### First Embodiment

FIG. 2A is a schematic sectional view of a memory cell in the semiconductor memory device of the first embodiment. FIG. 2B is a band diagram under application of electric field to the tunnel insulating film of the memory cell of the semiconductor memory device of the first embodiment.

According to the first embodiment, a high-k insulating film 52 is provided on the inner peripheral surface of the first tunnel insulating film 41 on the channel body 20 side. That is, the high-k insulating film 52 is provided between the channel body 20 and the first tunnel insulating film 41.

Furthermore, a high-k insulating film 51 is provided on the outer peripheral surface of the first tunnel insulating film 41 located on the third tunnel insulating film 42 side. That is, the high-k insulating film 51 is provided between the first tunnel insulating film 41 and the third tunnel insulating film 42.

The first tunnel insulating film 41 is sandwiched between the high-k insulating film 52 and the high-k insulating film 51. The high-k insulating film 52 and the high-k insulating film 51 have a lower surface density of oxygen atoms than the first tunnel insulating film 41, and have a higher permittivity than silicon nitride.

The first tunnel insulating film 41 is e.g. a silicon oxide film (SiO₂ film). The high-k insulating film 52 and the high-k insulating film 51 are e.g. metal compound films containing at least one of lanthanum (La), yttrium (Y), strontium (Sr), and lutetium (Lu).

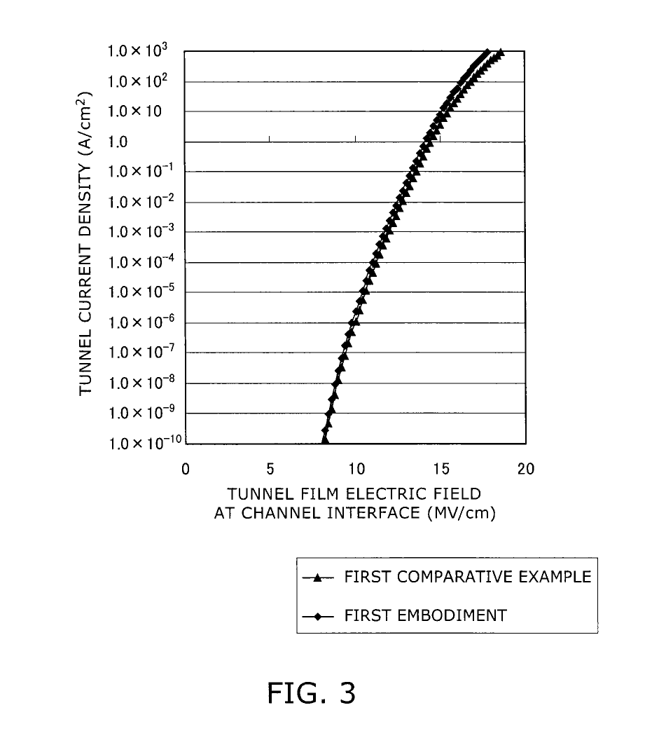

FIG. 3 is a current-electric field characteristic diagram of the tunnel insulating film in the first embodiment and a first comparative example. The horizontal axis represents the tunnel insulating film electric field (MV/cm) at the channel interface. The vertical axis represents the tunnel current density (A/cm²).

In the first embodiment in which the characteristic of FIG. 3 is obtained, the diameter of the memory hole (the diameter of the columnar part CL) is 56 nm. The block film 31 is a multilayer film including a Si₃N₄ film (film thickness 1.4 nm), a SiO₂ film (film thickness 3.1 nm), a Si₃N₄ film (film thickness 2.0 nm), and a SiO₂ film (film thickness 3.5 nm) provided sequentially from the electrode layer WL side. The charge storage film 32 is a Si₃N₄ film (film thickness 3.0 nm).

The first tunnel insulating film 41 is a SiO₂ film (film thickness 1.2 nm). The second tunnel insulating film 43 is a SiO₂ film (film thickness 4.0 nm). The third tunnel insulating film 42 is a Si₃N₄ film (film thickness 1.0 nm).

The high-k insulating film 52 and the high-k insulating film 51 are each a La₂O₃ film (film thickness 0.3 nm).

The first comparative example has a structure lacking the high-k insulating film 52 and the high-k insulating film 51 in the above first embodiment.

According to the first embodiment, on both surfaces (inner peripheral surface and outer peripheral surface) of the first tunnel insulating film 41 located on the channel body 20 side, the high-k insulating films (La₂O₃ films) 52, 51 having a lower surface density of oxygen atoms than the first tunnel insulating film (SiO₂ film) 41 are provided.

Thus, dipoles having an orientation of decreasing the conduction band barrier height of the first tunnel insulating film 41 can be formed at the interface between the first tunnel insulating film 41 and the high-k insulating film 52 and the interface between the first tunnel insulating film 41 and the high-k insulating film 51. Accordingly, the conduction band barrier height of the first tunnel insulating film 41 was successfully decreased by 0.3 eV without changing the permittivity of the first tunnel insulating film 41.

The decrease of the conduction band barrier height of the first tunnel insulating film 41 located on the channel side results in increasing the tunnel current density in the high electric field region. That is, as shown in FIG. 3, in the first embodiment, compared with the first comparative example lacking the high-k insulating films 52, 51, increase of the tunnel current was observed in the high electric field region. In other words, the current-electric field characteristic of the tunnel insulating film was successfully made steep.

In this specification, the term “high electric field region” with regard to the electric field of the tunnel insulating film refers to an electric field region of generally 10 MV/cm or more in terms of SiO₂-equivalent electric field. The term “medium electric field region” refers to an electric field region of generally 5 MV/cm or more and less than 10 MV/cm in terms of SiO₂-equivalent electric field.

The high electric field region corresponds to a region of electric field applied to the tunnel insulating film at the time of writing data to the memory cell. Thus, by the increase of the tunnel current (improvement in electron injection efficiency) in the high electric field region, the writing speed (writing efficiency) can be improved.

### Second Embodiment

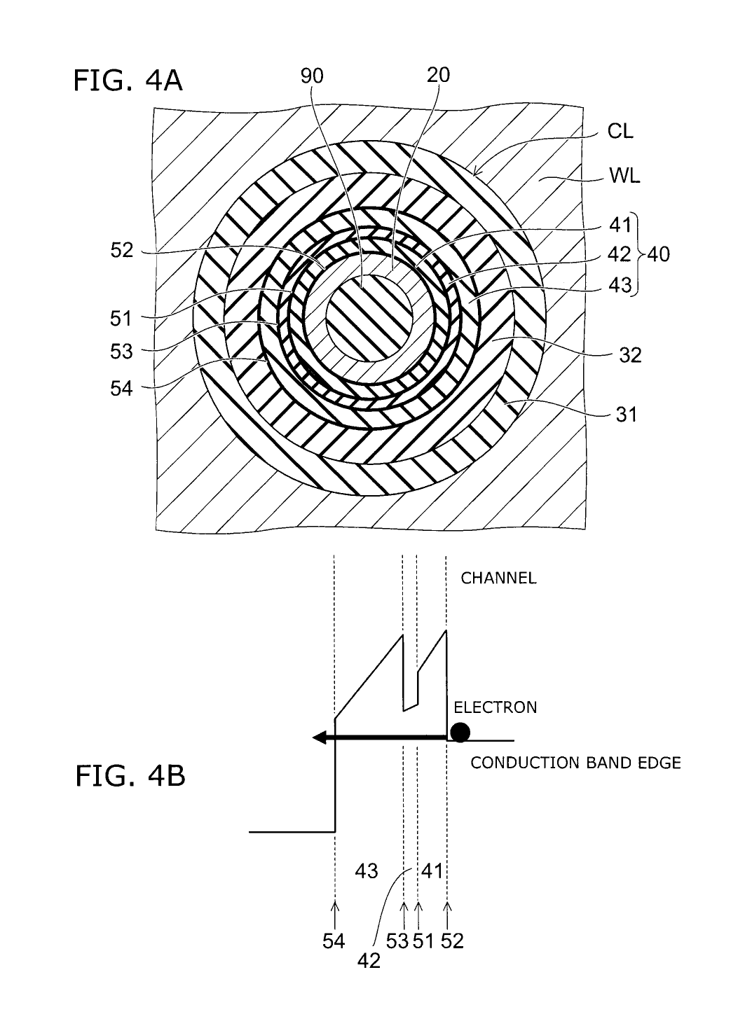

FIG. 4A is a schematic sectional view of a memory cell in a semiconductor memory device of a second embodiment. FIG. 4A shows a cross section along the diameter direction of the columnar part CL of the memory string.

FIG. 4B is a band diagram under application of electric field to the tunnel insulating film of the memory cell of the semiconductor memory device of the second embodiment.

According to the second embodiment, as in the first embodiment, a high-k insulating film 52 is provided on the inner peripheral surface of the first tunnel insulating film 41 located on the channel body 20 side. That is, the high-k insulating film 52 is provided between the channel body 20 and the first tunnel insulating film 41.

Furthermore, a high-k insulating film 51 is provided on the outer peripheral surface of the first tunnel insulating film 41 located on the third tunnel insulating film 42 side. That is, the high-k insulating film 51 is provided between the first tunnel insulating film 41 and the third tunnel insulating film 42.

The first tunnel insulating film 41 is sandwiched between the high-k insulating film 52 and the high-k insulating film 51. The high-k insulating film 52 and the high-k insulating film 51 have a lower surface density of oxygen atoms than the first tunnel insulating film 41, and have a higher permittivity than silicon nitride.

Furthermore, according to the second embodiment, a high-k insulating film 53 is provided on the inner peripheral surface of the second tunnel insulating film 43 located on the third tunnel insulating film 42 side. That is, the high-k insulating film 53 is provided between the second tunnel insulating film 43 and the third tunnel insulating film 42.

Furthermore, a high-k insulating film 54 is provided on the outer peripheral surface of the second tunnel insulating film 43 located on the charge storage film 32 side. That is, the high-k insulating film 54 is provided between the charge storage film 32 and the second tunnel insulating film 43.

The second tunnel insulating film 43 is sandwiched between the high-k insulating film 53 and the high-k insulating film 54. The high-k insulating film 53 and the high-k insulating film 54 have a higher surface density of oxygen atoms than the second tunnel insulating film 43, and have a higher permittivity than silicon nitride.

The second tunnel insulating film 43 is e.g. a silicon oxynitride film (SiON film). The high-k insulating film 53 and the high-k insulating film 54 are e.g. metal compound films containing at least one of aluminum (Al), titanium (Ti), tantalum (Ta), magnesium (Mg), hafnium (Hf), zirconium (Zr), and scandium (Sc).

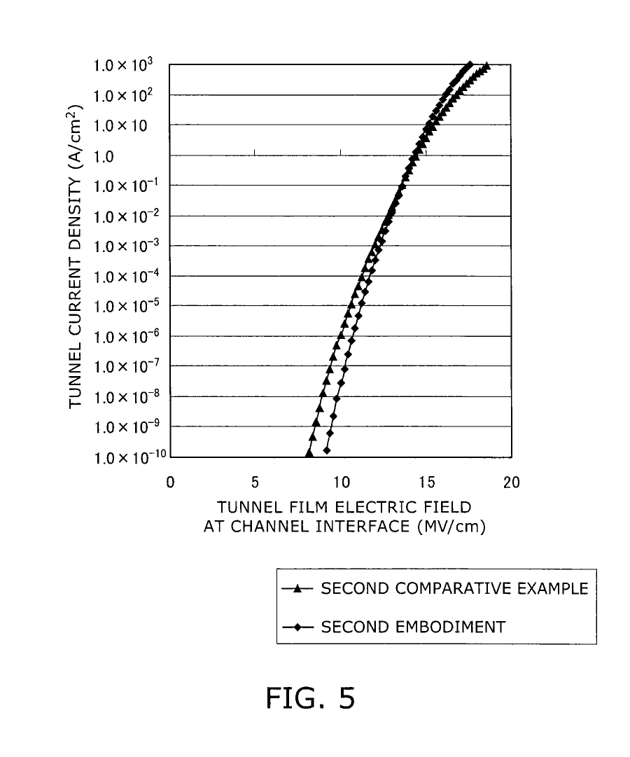

FIG. 5 is a current-electric field characteristic diagram of the tunnel insulating film in the second embodiment and a second comparative example. The horizontal axis represents the tunnel insulating film electric field (MV/cm) at the channel interface. The vertical axis represents the tunnel current density (A/cm²).

In the second embodiment in which the characteristic of FIG. 5 is obtained, the diameter of the memory hole (the diameter of the columnar part CL) is 56 nm. The block film 31 is a multilayer film including a Si₃N₄ film (film thickness 1.4 nm), a SiO₂ film (film thickness 3.1 nm), a Si₃N₄ film (film thickness 2.0 nm), and a SiO₂ film (film thickness 3.5 nm) provided sequentially from the electrode layer WL side. The charge storage film 32 is a Si₃N₄ film (film thickness 3.0 nm).

The first tunnel insulating film 41 is a SiO₂ film (film thickness 1.2 nm). The second tunnel insulating film 43 is a SiON film (film thickness 4.0 nm). The third tunnel insulating film 42 is a Si₃N₄ film (film thickness 1.0 nm).

The high-k insulating film 53 and the high-k insulating film 54 are each an Al₂O₃ film (film thickness 0.3 nm).

The second comparative example has a structure lacking the high-k insulating films 51-54 in the above second embodiment.

According to the second embodiment, on both surfaces (inner peripheral surface and outer peripheral surface) of the first tunnel insulating film 41 located on the channel body 20 side, the high-k insulating films (La₂O₃ films) 52, 51 having a lower surface density of oxygen atoms than the first tunnel insulating film (SiO₂ film) 41 are provided.

Thus, dipoles having an orientation of decreasing the conduction band barrier height of the first tunnel insulating film 41 can be formed at the interface between the first tunnel insulating film 41 and the high-k insulating film 52 and the interface between the first tunnel insulating film 41 and the high-k insulating film 51. Accordingly, the conduction band barrier height of the first tunnel insulating film 41 was successfully decreased by 0.3 eV without changing the permittivity of the first tunnel insulating film 41.

The decrease of the conduction band barrier height of the first tunnel insulating film 41 located on the channel side results in increasing the tunnel current density in the high electric field region. That is, as shown in FIG. 5, in the second embodiment, compared with the second comparative example lacking the high-k insulating films 52, 51, increase of the tunnel current was observed in the high electric field region.

Furthermore, according to the second embodiment, on both surfaces (inner peripheral surface and outer peripheral surface) of the second tunnel insulating film 43 located on the charge storage film 32 side, the high-k insulating films (Al₂O₃ films) 53, 54 having a higher surface density of oxygen atoms than the second tunnel insulating film (SiON film) 43 are provided.

Thus, dipoles having an orientation of increasing the conduction band barrier height of the second tunnel insulating film 43 can be formed at the interface between the second tunnel insulating film 43 and the high-k insulating film 53 and the interface between the second tunnel insulating film 43 and the high-k insulating film 54. Accordingly, the conduction band barrier height of the second tunnel insulating film 43 was successfully increased by 0.55 eV without changing the permittivity of the second tunnel insulating film 43.

The increase of the conduction band barrier height of the second tunnel insulating film 43 located on the charge storage film 32 side results in decreasing the tunnel current density in the medium electric field region. That is, as shown in FIG. 5, in the second embodiment, compared with the second comparative example lacking the high-k insulating films 53, 54, decrease of the tunnel current was observed in the medium electric field region.

The medium electric field region corresponds to a region of electric field applied to the tunnel insulating film at the time of reading data in the memory cell. Thus, charge injection (leakage current) at read time can be suppressed, and the read disturb tolerance of the memory cell can be improved.

That is, the second embodiment can simultaneously realize current increase in the high electric field region and leakage current suppression in the medium electric field region of the tunnel insulating film. Thus, a tunnel insulating film having a steep current-electric field characteristic (J-E characteristic) is obtained.

Accordingly, while improving the read disturb tolerance of the memory cell, the writing efficiency can be simultaneously increased. This allows expansion of the threshold voltage window in the operation of the memory cell.

As the first tunnel insulating film 41, besides the silicon oxide film (SiO₂ film), a silicon oxynitride film (SiON film) doped with a quantity of nitrogen can also be used to achieve a similar effect. Also in this case, on both surfaces (inner peripheral surface and outer peripheral surface) of the first tunnel insulating film 41, high-k insulating films having a lower surface density of oxygen atoms than the first tunnel insulating film 41 are provided.

If high-k insulating films having a very great effect of increasing the conduction band barrier height of the second tunnel insulating film 43 are provided on both surfaces (inner peripheral surface and outer peripheral surface) of the second tunnel insulating film 43, not only the current density in the medium electric field region but also that in the high electric field region may be affected. Then, the effect of increasing the tunnel current in the high electric field region may be suppressed.

In this case, by using a SiON film as the second tunnel insulating film 43, the barrier height increase can be alleviated, resulting in the balance between current increase in the high electric field region and current decrease in the medium electric field region. That is, a current-electric field characteristic with a large current density in the high electric field region and a small current density in the medium electric field region is obtained.

### Third Embodiment

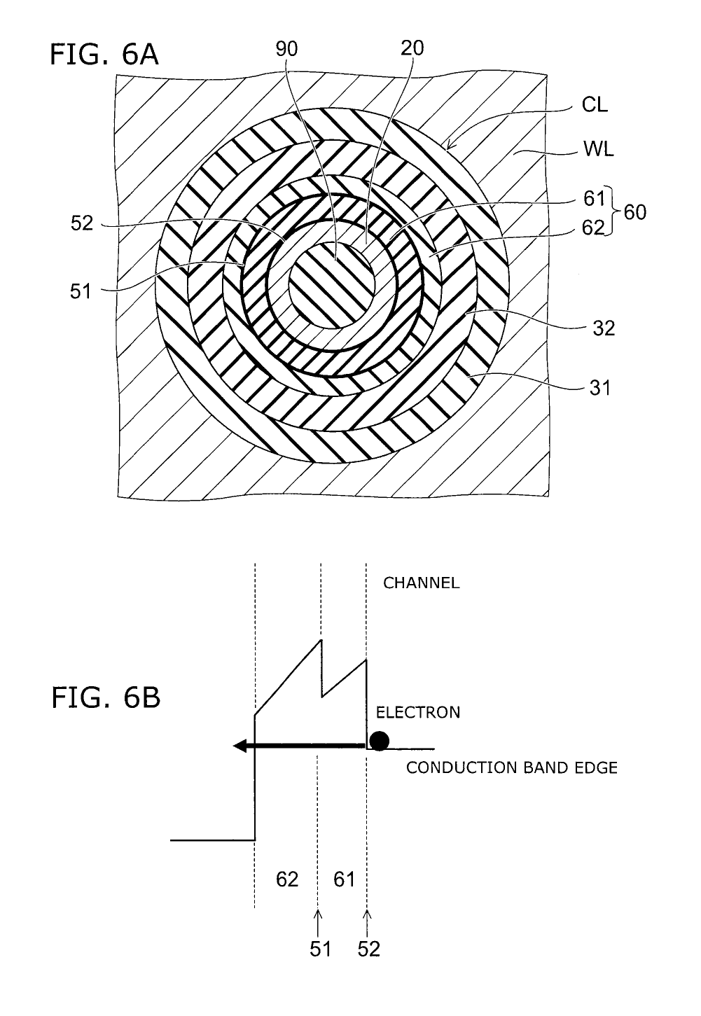

FIG. 6A is a schematic sectional view of a memory cell in a semiconductor memory device of a third embodiment. FIG. 6A shows a cross section along the diameter direction of the columnar part CL of the memory string.

FIG. 6B is a band diagram under application of electric field to the tunnel insulating film of the memory cell of the semiconductor memory device of the third embodiment.

According to the third embodiment, between the channel body 20 and the charge storage film 32, a tunnel insulating film 60 made of two layers is provided. The tunnel insulating film 60 contains silicon, oxygen, and nitrogen.

The tunnel insulating film 60 includes a first tunnel insulating film 61 and a second tunnel insulating film 62.

The first tunnel insulating film 61 is provided in a tubular shape around the channel body 20. The first tunnel insulating film 61 is e.g. a silicon oxynitride film.

The second tunnel insulating film 62 is provided in a tubular shape on the inner peripheral surface of the charge storage film 32. The second tunnel insulating film 62 is e.g. a silicon oxide film.

Furthermore, according to the third embodiment, as in the above embodiments, a high-k insulating film 52 is provided on the inner peripheral surface of the first tunnel insulating film 61 located on the channel body 20 side. That is, the high-k insulating film 52 is provided between the channel body 20 and the first tunnel insulating film 61.

Furthermore, a high-k insulating film 51 is provided on the outer peripheral surface of the first tunnel insulating film 61 located on the second tunnel insulating film 62 side. That is, the high-k insulating film 51 is provided between the first tunnel insulating film 61 and the second tunnel insulating film 62.

The first tunnel insulating film 61 is sandwiched between the high-k insulating film 52 and the high-k insulating film 51. The high-k insulating film 52 and the high-k insulating film 51 have a lower surface density of oxygen atoms than the first tunnel insulating film 61, and have a higher permittivity than silicon nitride.

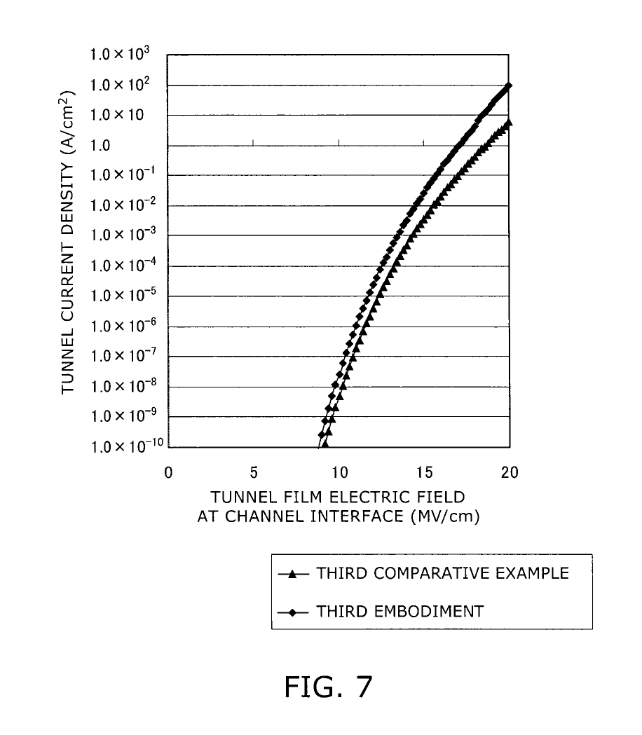

FIG. 7 is a current-electric field characteristic diagram of the tunnel insulating film in the third embodiment and a third comparative example. The horizontal axis represents the tunnel insulating film electric field (MV/cm) at the channel interface. The vertical axis represents the tunnel current density (A/cm²). The electric field on the horizontal axis is represented by a value converted to SiO₂ electric field.

In the third embodiment in which the characteristic of FIG. 7 is obtained, the diameter of the memory hole (the diameter of the columnar part CL) is 56 nm. The block film 31 is a multilayer film including a Si₃N₄ film (film thickness 1.4 nm), a SiO₂ film (film thickness 3.1 nm), a Si₃N₄ film (film thickness 2.0 nm), and a SiO₂ film (film thickness 3.5 nm) provided sequentially from the electrode layer WL side. The charge storage film 32 is a Si₃N₄ film (film thickness 3.0 nm).

The first tunnel insulating film 61 is a SiON film (film thickness 2.2 nm). The second tunnel insulating film 62 is a SiO₂ film (film thickness 4.0 nm).

The high-k insulating film 52 and the high-k insulating film 51 are each a La₂O₃ film (film thickness 0.3 nm).

The third comparative example has a structure lacking the high-k insulating film 52 and the high-k insulating film 51 in the above third embodiment.

According to the third embodiment, on both surfaces (inner peripheral surface and outer peripheral surface) of the first tunnel insulating film 61 located on the channel body 20 side, the high-k insulating films (La₂O₃ films) 52, 51 having a lower surface density of oxygen atoms than the first tunnel insulating film (SiON film) 61 are provided.

Thus, dipoles having an orientation of decreasing the conduction band barrier height of the first tunnel insulating film 61 can be formed at the interface between the first tunnel insulating film 61 and the high-k insulating film 52 and the interface between the first tunnel insulating film 61 and the high-k insulating film 51. Accordingly, the conduction band barrier height of the first tunnel insulating film 61 was successfully decreased by 0.3 eV without changing the permittivity of the first tunnel insulating film 61.

The decrease of the conduction band barrier height of the first tunnel insulating film 61 located on the channel side results in increasing the tunnel current density in the high electric field region. That is, as shown in FIG. 7, in the third embodiment, compared with the third comparative example lacking the high-k insulating films 52, 51, increase of the tunnel current was observed in the high electric field region. In other words, the current-electric field characteristic of the tunnel insulating film was successfully made steep. Thus, by the increase of the tunnel current (improvement in electron injection efficiency) in the high electric field region, the writing speed (writing efficiency) can be improved.

### Fourth Embodiment

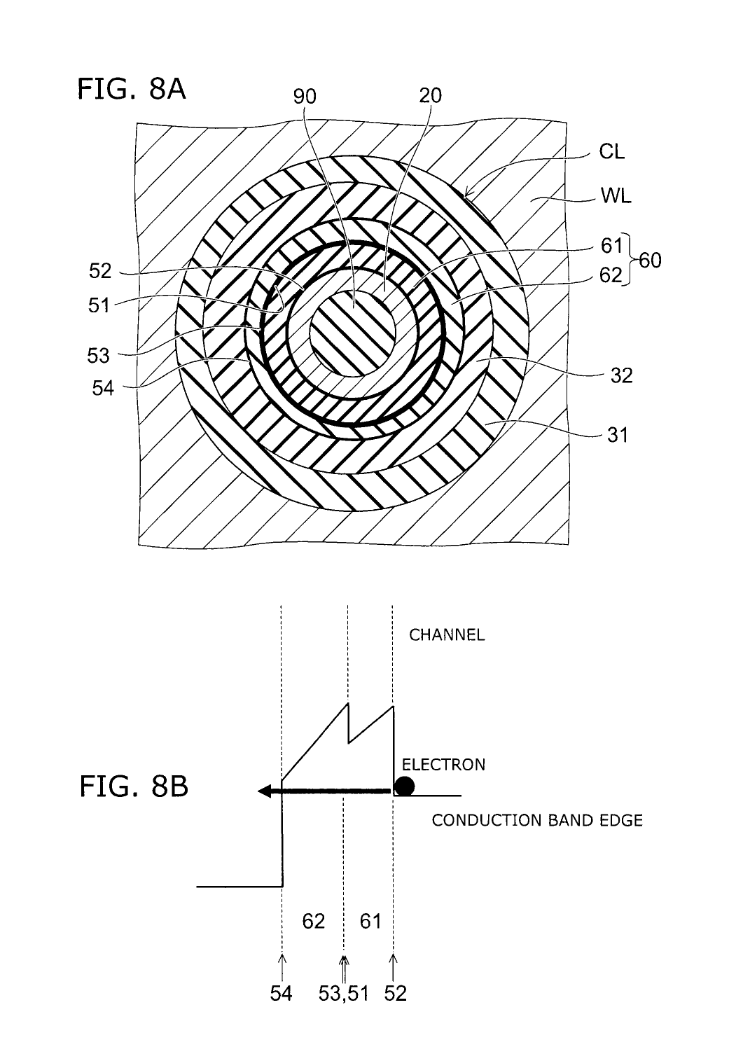

FIG. 8A is a schematic sectional view of a memory cell in a semiconductor memory device of a fourth embodiment. FIG. 8A shows a cross section along the diameter direction of the columnar part CL of the memory string.

FIG. 8B is a band diagram under application of electric field to the tunnel insulating film of the memory cell of the semiconductor memory device of the fourth embodiment.

As in the third embodiment, the memory cell of the fourth embodiment includes a tunnel insulating film 60 made of a multilayer film of two layers.

According to the fourth embodiment, as in the third embodiment, a high-k insulating film 52 is provided on the inner peripheral surface of the first tunnel insulating film 61 located on the channel body 20 side. That is, the high-k insulating film 52 is provided between the channel body 20 and the first tunnel insulating film 61.

Furthermore, a high-k insulating film 51 is provided on the outer peripheral surface of the first tunnel insulating film 61 on the second tunnel insulating film 62 side. That is, the high-k insulating film 51 is provided between the first tunnel insulating film 61 and the second tunnel insulating film 62.

The first tunnel insulating film 61 is sandwiched between the high-k insulating film 52 and the high-k insulating film 51. The high-k insulating film 52 and the high-k insulating film 51 have a lower surface density of oxygen atoms than the first tunnel insulating film 61, and have a higher permittivity than silicon nitride.

Furthermore, according to the fourth embodiment, a high-k insulating film 53 is provided on the inner peripheral surface of the second tunnel insulating film 62 located on the first tunnel insulating film 61 side. The high-k insulating film 53 is in contact with the high-k insulating film 51. That is, the high-k insulating film 53 is provided between the second tunnel insulating film 62 and the high-k insulating film 51.

Furthermore, a high-k insulating film 54 is provided on the outer peripheral surface of the second tunnel insulating film 62 located on the charge storage film 32 side. That is, the high-k insulating film 54 is provided between the charge storage film 32 and the second tunnel insulating film 62.

The second tunnel insulating film 62 is sandwiched between the high-k insulating film 53 and the high-k insulating film 54. The high-k insulating film 53 and the high-k insulating film 54 have a higher surface density of oxygen atoms than the second tunnel insulating film 62, and have a higher permittivity than silicon nitride.

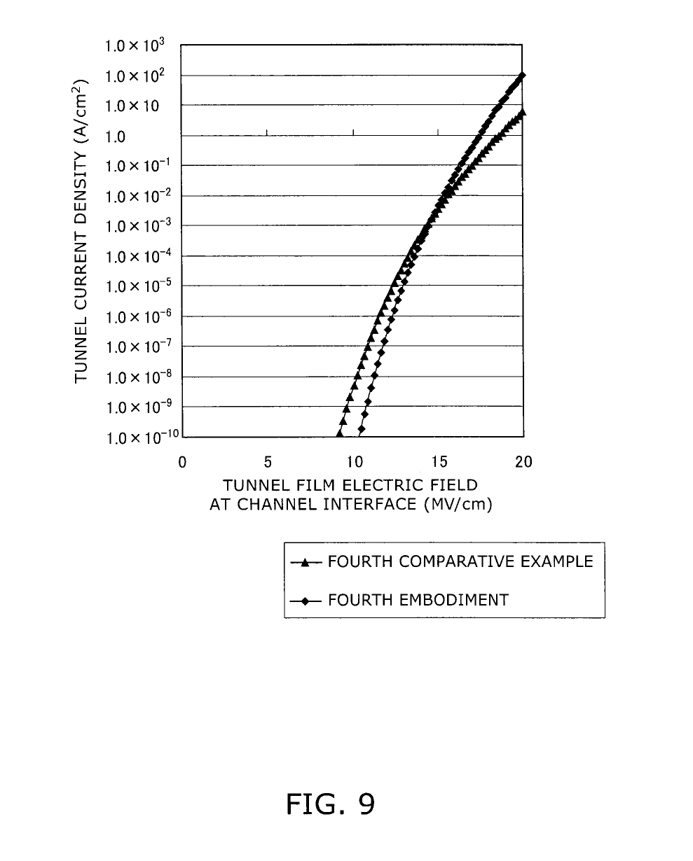

FIG. 9 is a current-electric field characteristic diagram of the tunnel insulating film in the fourth embodiment and a fourth comparative example. The horizontal axis represents the tunnel insulating film electric field (MV/cm) at the channel interface. The vertical axis represents the tunnel current density (A/cm²). The electric field on the horizontal axis is represented by a value converted to SiO₂ electric field.

In the fourth embodiment in which the characteristic of FIG. 9 is obtained, the diameter of the memory hole (the diameter of the columnar part CL) is 56 nm. The block film 31 is a multilayer film including a Si₃N₄ film (film thickness 1.4 nm), a SiO₂ film (film thickness 3.1 nm), a Si₃N₄ film (film thickness 2.0 nm), and a SiO₂ film (film thickness 3.5 nm) provided sequentially from the electrode layer WL side. The charge storage film 32 is a Si₃N₄ film (film thickness 3.0 nm).

The first tunnel insulating film 61 is a SiON film (film thickness 2.2 nm). The second tunnel insulating film 62 is a SiON film (film thickness 4.0 nm).

The high-k insulating film 53 and the high-k insulating film 54 are each an Al₂O₃ film (film thickness 0.3 nm).

The fourth comparative example has a structure lacking the high-k insulating films 51-54 in the above fourth embodiment.

According to the fourth embodiment, on both surfaces (inner peripheral surface and outer peripheral surface) of the first tunnel insulating film 61 located on the channel body 20 side, the high-k insulating films (La₂O₃ films) 52, 51 having a lower surface density of oxygen atoms than the first tunnel insulating film (SiON film) 61 are provided.

Thus, dipoles having an orientation of decreasing the conduction band barrier height of the first tunnel insulating film 61 can be formed at the interface between the first tunnel insulating film 61 and the high-k insulating film 52 and the interface between the first tunnel insulating film 61 and the high-k insulating film 51. Accordingly, the conduction band barrier height of the first tunnel insulating film 61 was successfully decreased by 0.3 eV without changing the permittivity of the first tunnel insulating film 61.

The decrease of the conduction band barrier height of the first tunnel insulating film 61 located on the channel side results in increasing the tunnel current density in the high electric field region. That is, as shown in FIG. 9, in the fourth embodiment, compared with the fourth comparative example lacking the high-k insulating films 52, 51, increase of the tunnel current was observed in the high electric field region.

Furthermore, according to the fourth embodiment, on both surfaces (inner peripheral surface and outer peripheral surface) of the second tunnel insulating film 62 located on the charge storage film 32 side, the high-k insulating films (Al₂O₃ films) 53, 54 having a higher surface density of oxygen atoms than the second tunnel insulating film (SiON film) 62 are provided.

Thus, dipoles having an orientation of increasing the conduction band barrier height of the second tunnel insulating film 62 can be formed at the interface between the second tunnel insulating film 62 and the high-k insulating film 53 and the interface between the second tunnel insulating film 62 and the high-k insulating film 54. Accordingly, the conduction band barrier height of the second tunnel insulating film 62 was successfully increased by 0.55 eV without changing the permittivity of the second tunnel insulating film 62.

The increase of the conduction band barrier height of the second tunnel insulating film 62 located on the charge storage film 32 side results in decreasing the tunnel current density in the medium electric field region. That is, as shown in FIG. 9, in the fourth embodiment, compared with the fourth comparative example lacking the high-k insulating films 53, 54, decrease of the tunnel current was observed in the medium electric field region.

That is, the fourth embodiment can simultaneously realize current increase in the high electric field region and leakage current suppression in the medium electric field region of the tunnel insulating film. Thus, a tunnel insulating film having a steep current-electric field characteristic (J-E characteristic) is obtained.

Accordingly, while improving the read disturb tolerance of the memory cell, the writing efficiency can be simultaneously increased. This allows expansion of the threshold voltage window in the operation of the memory cell.

Here, a silicon nitride film of approximately one monolayer may be provided between the high-k insulating film (La₂O₃ film) 51 and the high-k insulating film (Al₂O₃ film) 53. This can prevent mixing between the La₂O₃ film and the Al₂O₃ film in the thermal process at the time of forming memory cells.

In the above description of the embodiments, the memory string is formed in a U-shape in which the lower ends of a pair of columnar parts are joined in the back gate BG serving as a lower gate layer. However, the memory string may have an I-shaped straight structure penetrating through a lower gate layer (lower select gate), a stacked body stacked thereon including a plurality of electrode layers, and an upper gate layer (upper select gate) provided on the stacked body.

The multilayer film structure of the tunnel insulating film and the high-k insulating film of the above embodiments can also be applied to planar memory cells.

### Fifth Embodiment

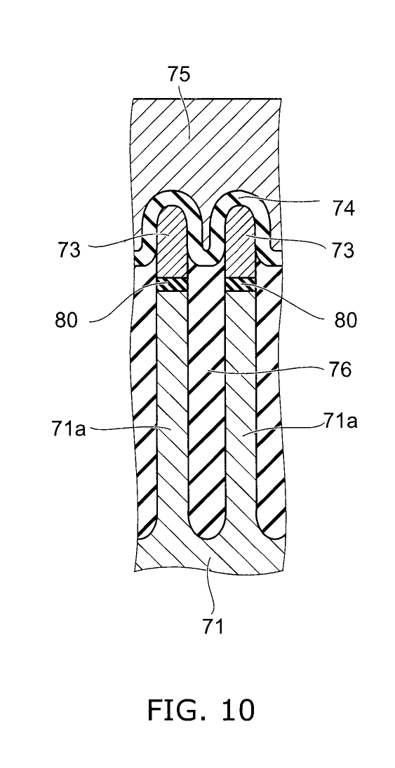

FIG. 10 is a schematic sectional view of a memory cell of a semiconductor memory device of a fifth embodiment.

In the surface of a semiconductor substrate 71 or the surface of a well layer formed in the surface of the semiconductor substrate 71, an active region 71a as a semiconductor channel is formed. The active region 71a extends in the direction penetrating through the page of FIG. 10.

A plurality of active regions 71a are provided in a fin shape. An insulating film 76 is embedded between the adjacent active regions 71a.

On the upper surface of the active region 71a, a tunnel insulating film 80 is provided. On the tunnel insulating film 80, a charge storage film 73 is provided. The charge storage film 73 is e.g. a floating gate electrode, a trap insulating film, or a multilayer film thereof.

On the charge storage film 73, an intermediate insulating film 74 is provided. The intermediate insulating film 74 is provided also on the side surface of the charge storage film 73. On the intermediate insulating film 74, a control gate 75 is provided as an electrode layer.

In plan view with the substrate 71 viewed from above in FIG. 10, the active region 71a and the control gate 75 intersect with (e.g., are orthogonal to) each other. At the intersection thereof, the charge storage film 73 is located. That is, on the substrate 71, a plurality of memory cells are laid out in a matrix. One memory cell includes one charge storage film 73 surrounded with insulator.

The charge storage film 73 is covered with insulator, and electrically connected to nowhere. Thus, even when powered off, the electrons accumulated in the charge storage film 73 do not leak out of the charge storage film 73. Furthermore, no electron is newly injected into the charge storage film 73. That is, the semiconductor memory device shown in FIG. 10 is a nonvolatile semiconductor memory device capable of retaining data without power supply.

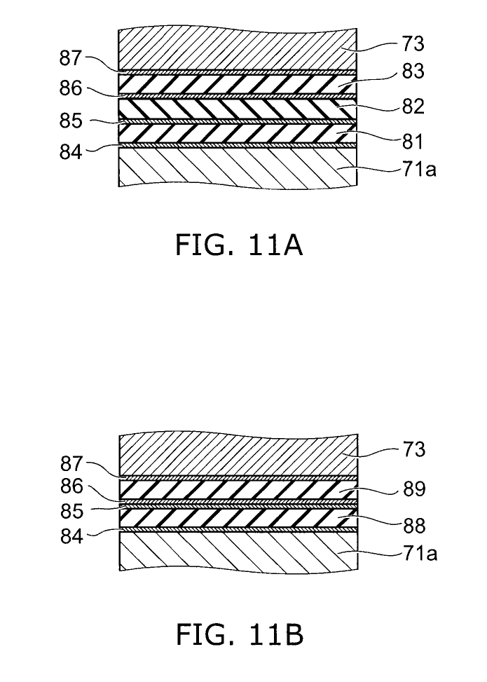

FIG. 11A is a schematic sectional view showing an example of the tunnel insulating film in the memory cell shown in FIG. 10.

The tunnel insulating film includes a first tunnel insulating film 81 provided on the active region 71a side, a second tunnel insulating film 83 provided on the charge storage film 73 side, and a third tunnel insulating film 82 provided between the first tunnel insulating film 81 and the second tunnel insulating film 83.

The first tunnel insulating film 81 and the second tunnel insulating film 83 are silicon oxide films or silicon oxynitride films. The third tunnel insulating film 82 has a higher nitrogen concentration than the first tunnel insulating film 81 and the second tunnel insulating film 83. The third tunnel insulating film 82 is e.g. a silicon nitride film or silicon oxynitride film. The term “nitrogen concentration” used herein refers to the volume density of nitrogen (the number of nitrogen atoms per unit volume).

Furthermore, a high-k insulating film 84 is provided on the lower surface of the first tunnel insulating film 81, i.e. on the active region 71a side. That is, the high-k insulating film 84 is provided between the active region 71a and the first tunnel insulating film 81.

Furthermore, a high-k insulating film 85 is provided on the upper surface of the first tunnel insulating film 81, i.e. on the third tunnel insulating film 82 side. That is, the high-k insulating film 85 is provided between the first tunnel insulating film 81 and the third tunnel insulating film 82.

The first tunnel insulating film 81 is sandwiched between the high-k insulating film 84 and the high-k insulating film 85. The high-k insulating film 84 and the high-k insulating film 85 have a lower surface density of oxygen atoms than the first tunnel insulating film 81, and have a higher permittivity than silicon nitride.

The high-k insulating film 84 and the high-k insulating film 85 are e.g. metal compound films containing at least one of lanthanum (La), yttrium (Y), strontium (Sr), and lutetium (Lu).

Moreover, a high-k insulating film 86 is provided on the lower surface of the second tunnel insulating film 83, i.e. on the third tunnel insulating film 82 side. That is, the high-k insulating film 86 is provided between the second tunnel insulating film 83 and the third tunnel insulating film 82.

Furthermore, a high-k insulating film 87 is provided on the upper surface of the second tunnel insulating film 83, i.e. on the charge storage film 73 side. That is, the high-k insulating film 87 is provided between the charge storage film 73 and the second tunnel insulating film 83.

The second tunnel insulating film 83 is sandwiched between the high-k insulating film 86 and the high-k insulating film 87. The high-k insulating film 86 and the high-k insulating film 87 have a higher surface density of oxygen atoms than the second tunnel insulating film 83, and have a higher permittivity than silicon nitride.

The high-k insulating film 86 and the high-k insulating film 87 are e.g. metal compound films containing at least one of aluminum (Al), titanium (Ti), tantalum (Ta), magnesium (Mg), hafnium (Hf), zirconium (Zr), and scandium (Sc).

According to the fifth embodiment, on both surfaces (lower surface and upper surface) of the first tunnel insulating film 81 located on the active region (channel) 71a side, the high-k insulating films 84, 85 having a lower surface density of oxygen atoms than the first tunnel insulating film 81 are provided.

Thus, dipoles having an orientation of decreasing the conduction band barrier height of the first tunnel insulating film 81 can be formed at the interface between the first tunnel insulating film 81 and the high-k insulating film 84 and the interface between the first tunnel insulating film 81 and the high-k insulating film 85. Accordingly, the conduction band barrier height of the first tunnel insulating film 81 can be decreased without changing the permittivity of the first tunnel insulating film 81.

The decrease of the conduction band barrier height of the first tunnel insulating film 81 located on the channel side results in increasing the tunnel current density in the high electric field region.

Furthermore, according to the fifth embodiment, on both surfaces (lower surface and upper surface) of the second tunnel insulating film 83 located on the charge storage film 73 side, the high-k insulating films 86, 87 having a higher surface density of oxygen atoms than the second tunnel insulating film 83 are provided.

Thus, dipoles having an orientation of increasing the conduction band barrier height of the second tunnel insulating film 83 can be formed at the interface between the second tunnel insulating film 83 and the high-k insulating film 86 and the interface between the second tunnel insulating film 83 and the high-k insulating film 87. Accordingly, the conduction band barrier height of the second tunnel insulating film 83 can be increased without changing the permittivity of the second tunnel insulating film 83.

The increase of the conduction band barrier height of the second tunnel insulating film 83 located on the charge storage film 73 side results in decreasing the tunnel current density in the medium electric field region.

That is, the fifth embodiment can simultaneously realize current increase in the high electric field region and leakage current suppression in the medium electric field region of the tunnel insulating film. Thus, a tunnel insulating film having a steep current-electric field characteristic (J-E characteristic) is obtained.

Accordingly, while improving the read disturb tolerance of the memory cell, the writing efficiency can be simultaneously increased. This allows expansion of the threshold voltage window in the operation of the memory cell.

FIG. 11B is a schematic sectional view showing an alternative configuration of the tunnel insulating film in the memory cell shown in FIG. 10.

In the structure of FIG. 11B, the tunnel insulating film includes a first tunnel insulating film 88 provided on the active region 71a side, and a second tunnel insulating film 89 provided on the charge storage film 73 side.

The first tunnel insulating film 88 is e.g. a silicon oxynitride film. The second tunnel insulating film 89 is e.g. a silicon oxide film or silicon oxynitride film.

Furthermore, a high-k insulating film 84 is provided on the lower surface of the first tunnel insulating film 88, i.e. on the active region 71a side. That is, the high-k insulating film 84 is provided between the active region 71a and the first tunnel insulating film 88.

Furthermore, a high-k insulating film 85 is provided on the upper surface of the first tunnel insulating film 88, i.e. on the second tunnel insulating film 89 side.

The first tunnel insulating film 88 is sandwiched between the high-k insulating film 84 and the high-k insulating film 85. The high-k insulating film 84 and the high-k insulating film 85 have a lower surface density of oxygen atoms than the first tunnel insulating film 88, and have a higher permittivity than silicon nitride.

Moreover, a high-k insulating film 86 is provided on the lower surface of the second tunnel insulating film 89, i.e. on the first tunnel insulating film 88 side. The high-k insulating film 86 is in contact with the high-k insulating film 85. That is, the high-k insulating film 86 is provided between the high-k insulating film 85 and the second tunnel insulating film 89.

Furthermore, a high-k insulating film 87 is provided on the upper surface of the second tunnel insulating film 89, i.e. on the charge storage film 73 side. That is, the high-k insulating film 87 is provided between the charge storage film 73 and the second tunnel insulating film 89.

The second tunnel insulating film 89 is sandwiched between the high-k insulating film 86 and the high-k insulating film 87. The high-k insulating film 86 and the high-k insulating film 87 have a higher surface density of oxygen atoms than the second tunnel insulating film 89, and have a higher permittivity than silicon nitride.

Also in the structure of FIG. 11B, on both surfaces (lower surface and upper surface) of the first tunnel insulating film 88 located on the active region (channel) 71a side, the high-k insulating films 84, 85 having a lower surface density of oxygen atoms than the first tunnel insulating film 88 are provided.

Thus, dipoles having an orientation of decreasing the conduction band barrier height of the first tunnel insulating film 88 can be formed at the interface between the first tunnel insulating film 88 and the high-k insulating film 84 and the interface between the first tunnel insulating film 88 and the high-k insulating film 85. Accordingly, the conduction band barrier height of the first tunnel insulating film 88 can be decreased without changing the permittivity of the first tunnel insulating film 88.

The decrease of the conduction band barrier height of the first tunnel insulating film 88 located on the channel side results in increasing the tunnel current density in the high electric field region.

Furthermore, on both surfaces (lower surface and upper surface) of the second tunnel insulating film 89 located on the charge storage film 73 side, the high-k insulating films 86, 87 having a higher surface density of oxygen atoms than the second tunnel insulating film 89 are provided.

Thus, dipoles having an orientation of increasing the conduction band barrier height of the second tunnel insulating film 89 can be formed at the interface between the second tunnel insulating film 89 and the high-k insulating film 86 and the interface between the second tunnel insulating film 89 and the high-k insulating film 87. Accordingly, the conduction band barrier height of the second tunnel insulating film 89 can be increased without changing the permittivity of the second tunnel insulating film 89.

The increase of the conduction band barrier height of the second tunnel insulating film 89 located on the charge storage film 73 side results in decreasing the tunnel current density in the medium electric field region.

That is, the structure of FIG. 11B can also simultaneously realize current increase in the high electric field region and leakage current suppression in the medium electric field region of the tunnel insulating film. Thus, a tunnel insulating film having a steep current-electric field characteristic (J-E characteristic) is obtained.

Accordingly, while improving the read disturb tolerance of the memory cell, the writing efficiency can be simultaneously increased. This allows expansion of the threshold voltage window in the operation of the memory cell.

Here, a silicon nitride film of approximately one monolayer may be provided between the high-k insulating film 85 and the high-k insulating film 86. This can prevent mixing between the high-k insulating film 85 and the high-k insulating film 86 in the thermal process at the time of forming memory cells.

According to the embodiments described above, the current-electric field characteristic of the tunnel insulating film is made steep by changing only the barrier height without changing the permittivity of the respective layers of the tunnel insulating film. Note that in the case where the film on the channel side of the multilayer tunnel insulating film is changed from SiO₂ to SiON, the effect of decreasing the barrier height is also obtained. However, this modulates the permittivity, as well. Thus, the current-electric field characteristic is not made steep. Accordingly, the introduction of the high-k insulating film as in the embodiments of the invention is necessary.

Here, the neutral threshold voltage of the memory cell may be increased by changing the impurity concentration of the channel or by changing the work function of the control gate electrode. From the viewpoint of the externally applied voltage, this could produce a state similar to the state of increased current density in the high electric field region and decreased current density in the medium electric field region.

However, for reasons of tradeoff with the threshold voltage of the select cell transistors, changing the neutral threshold voltage of the memory cell may be restricted. In contrast, in the present embodiments, the current-electric field characteristic of the tunnel insulating film can be made steep without changing the neutral threshold voltage of the memory cell.

Even if the high-k insulating film is provided on only one surface of the first tunnel insulating film located on the channel side, or only one surface of the second tunnel insulating film located on the charge storage film side, an effect qualitatively similar to that of the above embodiments is obtained. However, providing the high-k insulating film on both surfaces of the first tunnel insulating film or both surfaces of the second tunnel insulating film can suppress the deviation of the neutral threshold voltage of the memory cell which is caused by the existence of the high-k/SiO₂ dipole in only one direction.

It is recommended that the thickness of the above high-k insulating film is in the range from 1×10¹² cm⁻² to 1×10¹⁶ cm⁻² in terms of the surface density of the metallic element (the density integrated in the thickness direction). The thickness of the high-k insulating film may possibly be smaller than one monolayer.

For instance, examples of the high-k insulating film having a lower surface density of oxygen atoms than the SiO₂ film can include a La₂O₃ film, Y₂O₃ film, SrO film, and Lu₂O₃ film.

Examples of the high-k insulating film having a higher surface density of oxygen atoms than the SiO₂ film can include an Al₂O₃ film, TiO₂ film, Ta₂O₅ film, MgO film, HfO₂ film, ZrO₂ film, and Sc₂O₃ film.

The high-k insulating film is not limited to metal oxides, but may be made of a metal oxynitride, silicate, aluminate, nitride silicate, or nitride aluminate.

The surface density of oxygen atoms of the high-k insulating film can be determined by the method described in the literature (K. Kita and A. Toriumi, Appl. Phys. Lett. 94, 132902 (2009)).

More specifically, consider the structure containing one oxygen atom as a unit structure of each oxide (Si_{1/2}O, Al_{2/3}O, Hf_{1/2}O, Y_{2/3}O, La_{2/3}O). The formula weight thereof is denoted by Wu. Then, the volume Vu of this unit structure is given by Wu/ρ/N_{A} (N_{A}: Avogadro's number). By using the volume of this unit structure, the surface density σ of oxygen atoms per area can be determined to be Vu^{-2/3}.

By this method, the surface density of oxygen atoms can be determined also for an oxide, nitride, oxynitride, silicate, aluminate, nitride silicate, nitride aluminate and the like of an arbitrary metallic element.

Furthermore, also in the case where the tunnel insulating film is not made of SiO₂ but made of SiON, the composition thereof is expressed as (SiO₂)ₓ(Si₃N₄)₁₋ₓ. Then, the method described in the above literature of Kita et al. can be applied to determine the surface density of oxygen atoms.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device comprising:
a semiconductor channel;
an electrode layer;
a charge storage film provided between the semiconductor channel and the electrode layer;
a tunnel insulating film provided between the semiconductor channel and the charge storage film, containing silicon, oxygen, and nitrogen, and including at least a first tunnel insulating film provided on the semiconductor channel side and a second tunnel insulating film provided on the charge storage film side; and
a first insulating film provided on a surface of the first tunnel insulating film on opposite side from a surface on the semiconductor channel side, the first insulating film having a lower surface density of oxygen atoms than the first tunnel insulating film, and having a higher permittivity than silicon nitride.

2. The device according to claim 1, further comprising:
a second insulating film provided between the first tunnel insulating film and the semiconductor channel, the second insulating film having a lower surface density of oxygen atoms than the first tunnel insulating film, and having a higher permittivity than silicon nitride.

3. The device according to claim 1, further comprising:
a third insulating film provided on a surface of the second tunnel insulating film on opposite side from a surface on the charge storage film side, the third insulating film having a higher surface density of oxygen atoms than the second tunnel insulating film, and having a higher permittivity than silicon nitride.

4. The device according to claim 1, further comprising:
a fourth insulating film provided between the second tunnel insulating film and the charge storage film, the fourth insulating film having a higher surface density of oxygen atoms than the second tunnel insulating film, and having a higher permittivity than silicon nitride.

5. The device according to claim 1, further comprising:
a second insulating film provided between the first tunnel insulating film and the semiconductor channel, the second insulating film having a lower surface density of oxygen atoms than the first tunnel insulating film, and having a higher permittivity than silicon nitride;
a third insulating film provided on a surface of the second tunnel insulating film on opposite side from a surface on the charge storage film side, the third insulating film having a higher surface density of oxygen atoms than the second tunnel insulating film, and having a higher permittivity than silicon nitride; and
a fourth insulating film provided between the second tunnel insulating film and the charge storage film, the fourth insulating film having a higher surface density of oxygen atoms than the second tunnel insulating film, and having a higher permittivity than silicon nitride.

6. The device according to claim 1, wherein the first tunnel insulating film and the second tunnel insulating film contain silicon oxide or silicon oxynitride.

7. The device according to claim 1, wherein the tunnel insulating film further includes:
a third tunnel insulating film provided between the first insulating film and the second tunnel insulating film, the third tunnel insulating film having a higher nitrogen concentration than the first tunnel insulating film and the second tunnel insulating film.

8. The device according to claim 1, wherein the first insulating film contains at least one of lanthanum, yttrium, strontium, and lutetium.

9. The device according to claim 2, wherein the second insulating film contains at least one of lanthanum, yttrium, strontium, and lutetium.

10. The device according to claim 3, wherein the third insulating film contains at least one of aluminum, titanium, tantalum, magnesium, hafnium, zirconium, and scandium.

11. The device according to claim 4, wherein the fourth insulating film contains at least one of aluminum, titanium, tantalum, magnesium, hafnium, zirconium, and scandium.

12. The device according to claim 5, wherein
the first insulating film and the second insulating film contain at least one of lanthanum, yttrium, strontium, and lutetium, and
the third insulating film and the fourth insulating film contain at least one of aluminum, titanium, tantalum, magnesium, hafnium, zirconium, and scandium.

13. The device according to claim 1, wherein
the charge storage film, the tunnel insulating film, and the semiconductor channel penetrate through a stacked body in which a plurality of the electrode layers are stacked, and
the electrode layer surrounds the semiconductor channel via the charge storage film and the tunnel insulating film.

14. A semiconductor memory device comprising:
a semiconductor channel;
an electrode layer;
a charge storage film provided between the semiconductor channel and the electrode layer;
a tunnel insulating film provided between the semiconductor channel and the charge storage film, containing silicon, oxygen, and nitrogen, and including at least a first tunnel insulating film provided on the semiconductor channel side and a second tunnel insulating film provided on the charge storage film side; and
a first insulating film provided on a surface of the second tunnel insulating film on opposite side from a surface on the charge storage film side, the first insulating film having a higher surface density of oxygen atoms than the second tunnel insulating film, and having a higher permittivity than silicon nitride.

15. The device according to claim 14, further comprising:
a second insulating film provided between the second tunnel insulating film and the charge storage film, the second insulating film having a higher surface density of oxygen atoms than the second tunnel insulating film, and having a higher permittivity than silicon nitride.

16. The device according to claim 14, wherein the first insulating film contains at least one of aluminum, titanium, tantalum, magnesium, hafnium, zirconium, and scandium.

17. The device according to claim 15, wherein the second insulating film contains at least one of aluminum, titanium, tantalum, magnesium, hafnium, zirconium, and scandium.

18. The device according to claim 14, wherein the first tunnel insulating film and the second tunnel insulating film contain silicon oxide or silicon oxynitride.

19. The device according to claim 14, wherein the tunnel insulating film further includes:
a third tunnel insulating film provided between the first tunnel insulating film and the first insulating film, the third tunnel insulating film having a higher nitrogen concentration than the first tunnel insulating film and the second tunnel insulating film.

20. The device according to claim 14, wherein
the charge storage film, the tunnel insulating film, and the semiconductor channel penetrate through a stacked body in which a plurality of the electrode layers are stacked, and
the electrode layer surrounds the semiconductor channel via the charge storage film and the tunnel insulating film.
